(19) United States
(12) Patent Application Publication
(10) Pub. No.: US 2005/0007735 A1
(43) Pub. Date: Jan. 13, 2005

(54) Electronic apparatus having a reserve tank and a circulation path of liquid coolant for cooling a heat-generating component

(75) Inventors: Yukihiko Hata, Tokyo (JP); Kentaro Tomioka, Saitama-ken (JP); Mitsuyoshi Tanimoto, Kanagawa-ken (JP); Hiroyuki Kusaka, Tokyo (JP)

Correspondence Address: FOLEY & LARDNER, 2029 CENTURY PARK EAST, SUITE 3500, LOS ANGELES, CA, 90067, US

(73) Assignee: Kabushiki Kaisha Toshiba

(21) Appl. No.: 10/840,526

(22) Filed: May 5, 2004

(30) Foreign Application Priority Data
May 26, 2003 (JP) P2003-147804

(51) Int. Cl. H05K 7/20

(52) U.S. Cl. 361/687

(57) ABSTRACT

An electronic apparatus is provided with a circulating path used to circulate liquid coolant between a heat-receiving portion thermally connected to a CPU that generates heat and a heat-radiating portion that radiates heat generated in the CPU, so that the heat generated in the CPU is transferred to the heat-radiating portion by the liquid coolant. A reserve-tank is disposed in the circulating path and stores a portion of the liquid coolant for a reserve function. The circulating path includes a first tube to return the liquid coolant to the reserve-tank, and a second tube to lead the liquid coolant out from the reserve-tank. The second tube includes an inflow portion through which the liquid coolant inside the reserve-tank flows in, and the inflow portion is positioned at or near the center inside the reserve-tank.

### CROSS-REFERENCE TO RELATED APPLICATIONS

This application is based upon and claims the benefit of priority from the prior Japanese Patent Application No. 2003-147804, filed May 26, 2003.

### BACKGROUND OF THE INVENTION

1. Field of the Invention

The present invention relates to a liquid-cooling electronic apparatus that cools a heat-generating component, such as a semiconductor package and a chip set, with liquid coolant, and a structure adapted to separate air bubbles from liquid coolant circulating in a circulating path.

2. Description of the Related Art

Microprocessors for use in notebook-type portable computers generate more heat while operating, as they process data at higher speeds and perform more functions. Recently, so-called liquid-cooled cooling systems have been developed to cool the microprocessors.

U.S. Pat. No. 6,519,147 discloses a liquid-cooling system used in a notebook size portable computer including a body portion and a display portion. The cooling system is provided with a heat-receiving portion thermally connected to a heat-generating component, such as a CPU and a chip set, and a path filled with cooling liquid. The path is connected to the heat-receiving portion and is provided between the body portion and the display portion. The display portion accommodates a reserve-tank that reserves the cooling liquid. The reserve-tank supplies to the path with the cooling liquid, and is connected to the path through a check valve for backflow prevention.

U.S. Pat. No. 5,871,526 discloses a liquid-cooling system provided with a reserve-tank that supply to a liquid-circulating path with liquid, and the use of the reserve-tank as an air-liquid separator.

The separator disclosed in U.S. Pat. No. 5,871,526 includes a vessel containing liquid, a first path used to return the liquid circulating in the path to the vessel, and a second path used to lead the liquid out from the vessel. Each of the first and second paths includes an outlet and an inlet that open inside the vessel. The outlet of the first path opens to an air layer in the upper portion of the vessel, while the inlet of the second path opens in the vicinity of the bottom of the vessel.

In the notebook size portable computer disclosed in U.S. Pat. No. 6,519,147, the display portion with the reserve-tank is allowed to rotate between a closed position and an opened position. Incidentally, because the portable computer is placed in a bag or the like and carried along frequently, the posture of the portable computer is changed in various manners depending on the mode of usage. For this reason, the liquid level inside the reserve-tank is changed depending on the mode of usage. It is thus well anticipated that when the structure of the air-liquid separator disclosed in U.S. Pat. No. 5,871,526 is adapted to the reserve-tank disclosed in U.S. Pat. No. 6,519,147, turnover of the vessel may occur when the portable computer is in a given posture. This result in a problem that the inlet of the second path positioned in the bottom of the vessel comes above the liquid level, allowing air inside the vessel to be taken into the second path.

In the liquid-cooling system, once the cooling liquid gets mixed with air bubbles as a change in posture of the portable computer occurs, the performance of receiving the heat from the CPU in the heat-receiving portion is deteriorated.

### BRIEF SUMMARY OF THE INVENTION

Embodiments of the present invention is to provide an liquid-cooling system capable of a heat-generating component preventing liquid coolant from getting mixed with air bubbles even when the posture of the reserve-tank is changed.

According to one aspect of the invention, there is provided a liquid cooled electronic apparatus having a reserve tank. *******The reserve-tank is provided on the circulating path for storing a portion of the liquid coolant. The circulating path includes a first path for providing fluid communication of the liquid coolant to the reserve tank; and a second for providing fluid communication of the liquid coolant from the reserve tank. The second path has an inflow portion for intake of the liquid coolant from within the reserve-tank. The inflow portion is positioned at or near a center portion of the inside of the reserve-tank.

The liquid level within said reserve tank does not completely filing said reserve tank and leaves an air portion therein. The liquid level within said reserve tank and the position of said inflow portion are such that the inflow portion is constantly submerged below a liquid level of the liquid coolant for any orientation or attitude of the apparatus. In this manner, air bubbles will not enter the circulation path of the liquid coolant.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a perspective view of a portable computer showing a state where a display unit is rotated to a second position;

FIG. 2 is a perspective view of the portable computer showing a positional relation between the display unit and a supporting member when the display unit is rotated to the second position;

FIG. 3 is a perspective view of the portable computer showing a state where the display unit is moved to a third position;

FIG. 4 is a perspective view of the portable computer showing the positional relation between the display unit and the supporting member when the display unit is moved to the third position;

FIG. 5 is another perspective view of the portable computer showing the positional relation between the display unit and the supporting member when the display unit is moved to the third position;

FIG. 6 is a side view of the portable computer showing the positional relation between the display unit and the supporting member when the display unit is moved to the third position;

FIG. 7 is a perspective view of the portable computer showing a state where the display unit is rotated to a first position;

FIG. 8 is a cross section of the portable computer showing a positional relation among a heat-receiving portion accommodated in a body unit, a heat-radiating portion accommodated in the supporting member, and a circulating path used to circulate liquid coolant between the heat-receiving portion and the heat-radiating portion;

FIG. 9 is a plan view of a pump that serves also as the heat-receiving portion;

FIG. 10 is a cross section showing a positional relation between the pump and a CPU;

FIG. 11 is a plan view of a cooling apparatus;

FIG. 12 is a cross section showing a state where the heat-radiating portion is accommodated in a third housing;

FIG. 13 is a characteristic view showing a relation between a volume and a pressure of cooling air discharged through discharge ports when a range of opening of the discharge ports with respect to the rotational center of an impeller is varied;

FIG. 14 is a cross section showing a positional relation between the center of a reserve-tank and an inflow portion of a second path;

FIG. 15 is a cross section showing a positional relation between the inflow portion of the second path and the liquid level when the posture of the reserve-tank is changed; and

FIG. 16 is a cross section showing a positional relation between the inflow portion of the second path and the liquid level when the posture of the reserve-tank is changed further.

### DETAILED DESCRIPTION OF THE INVENTION

Embodiments of the present invention will be described, with reference to the accompanying drawings.

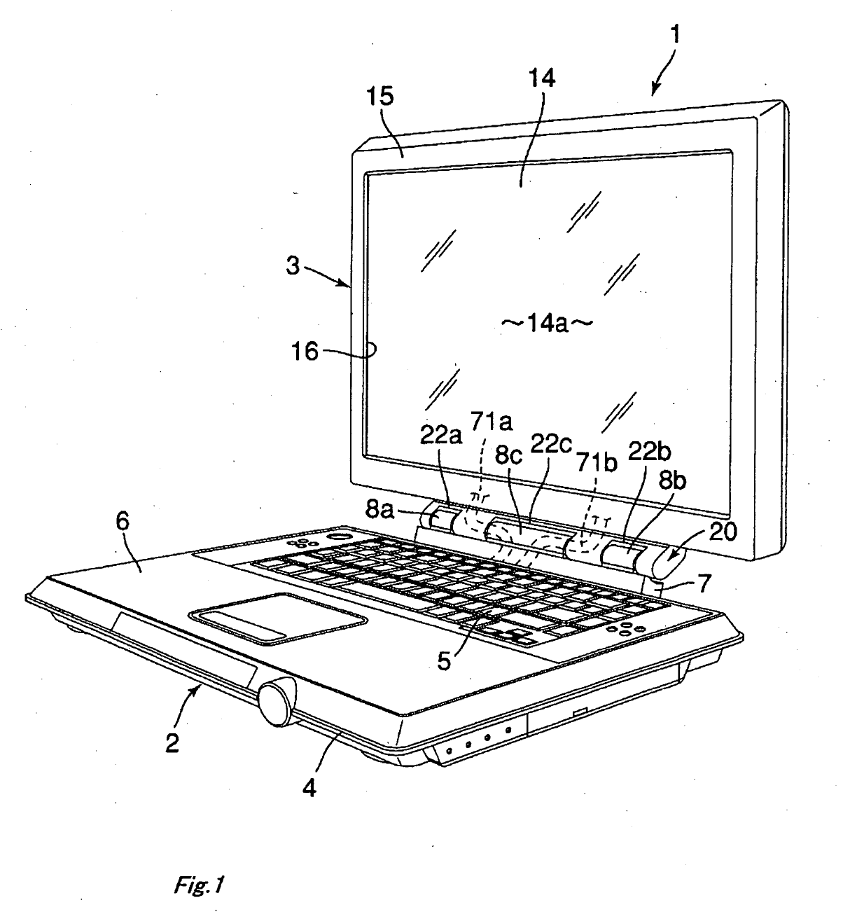

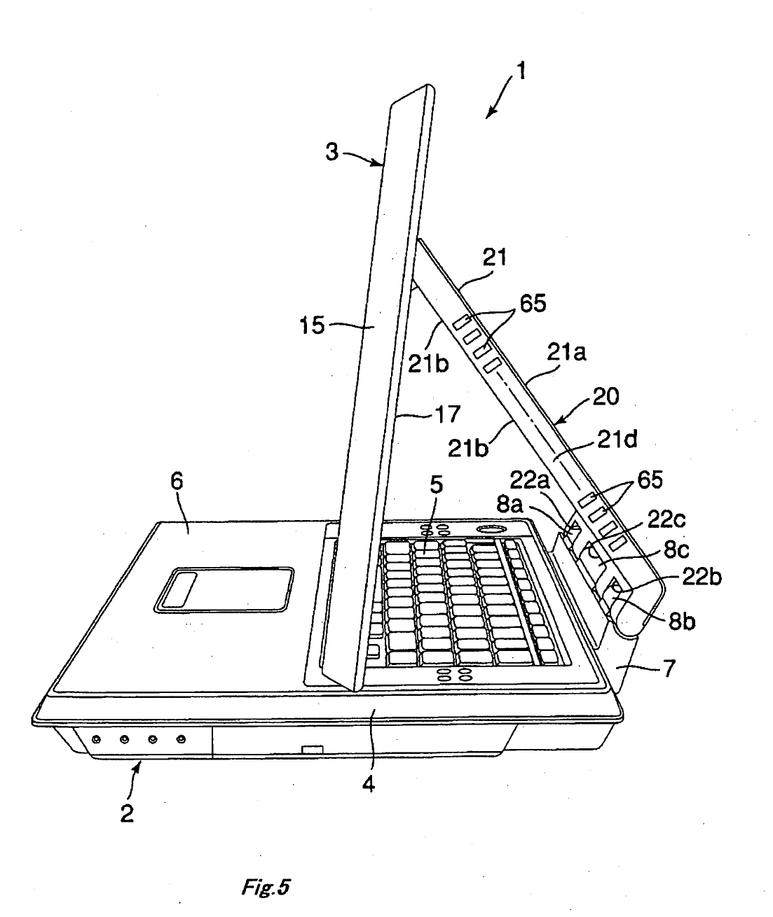

FIGS. 1 to 7 show a portable computer 1 as an electronic apparatus. The portable computer 1 is provided with a body 2 and a display unit 3. The body 2 includes a first housing 4 of a flat box-shape. The first housing 4 supports a keyboard 5 and the front half of the upper surface thereof defines a palm rest 6.

A mounting portion 7 is formed at the rear end portion of the first housing 4. The mounting portion 7 extends in the width direction of the first housing 4 while protruding upward above the upper surface of the first housing 4 and the keyboard 5. The mounting portion 7 includes first through third convex hollow portions 8a, 8b, and 8c. The first convex hollow portion 8a protrudes upward from one end of the mounting portion 7. The second convex hollow portion 8b protrudes upward from the other end of the mounting portion 7. The third convex hollow portion 8c protrudes upward from the center of the mounting portion 7 and is positioned between the first convex hollow portion 8a and the second convex hollow portion 8b.

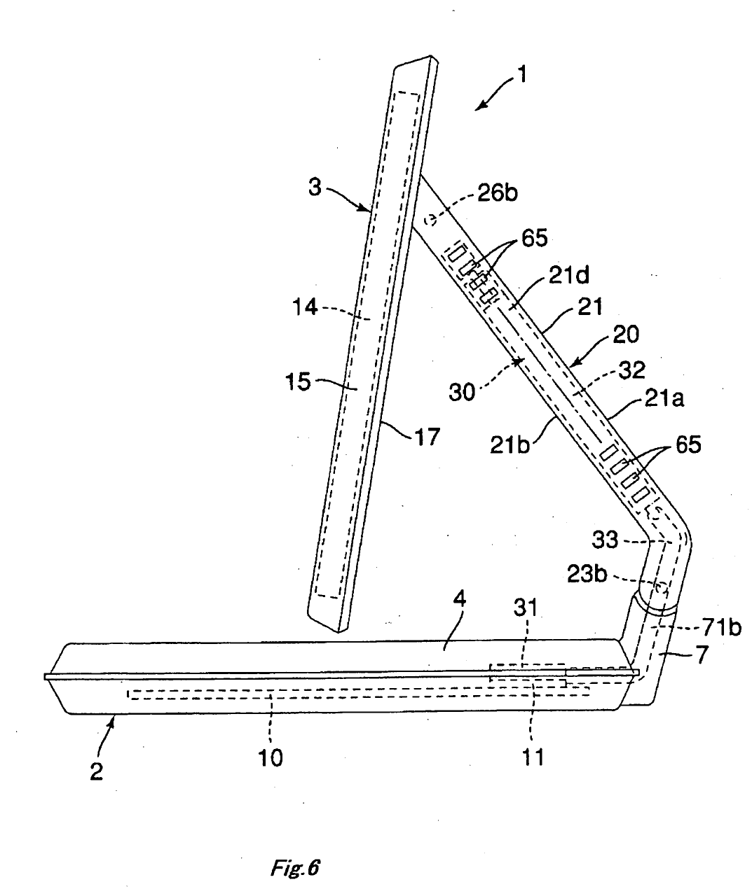

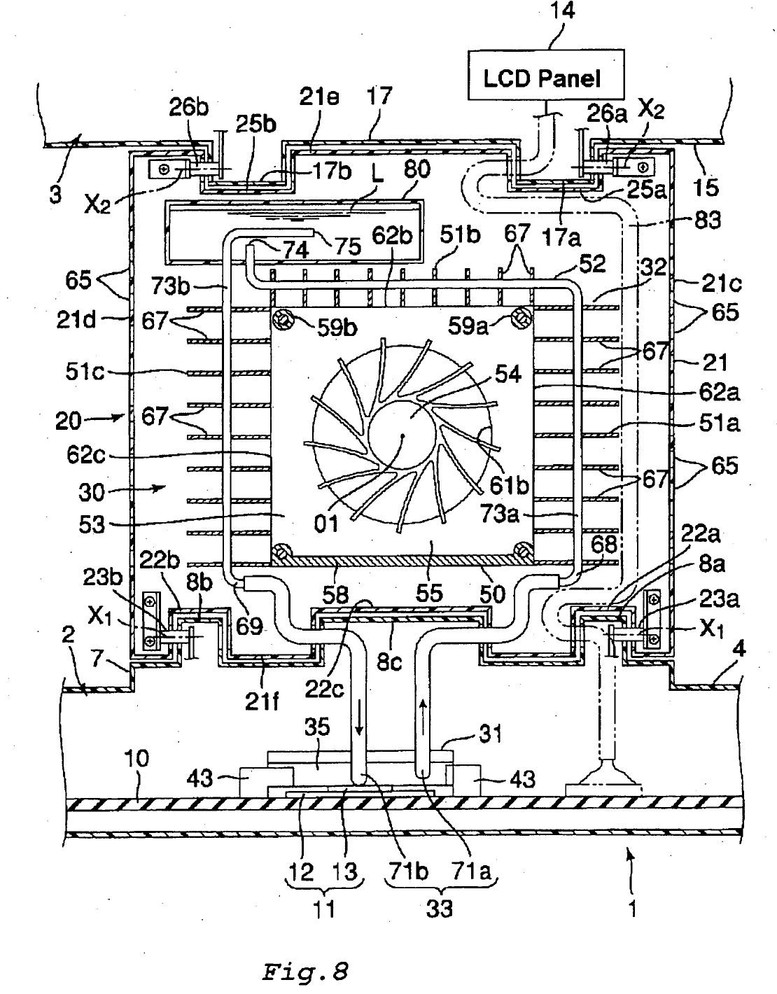

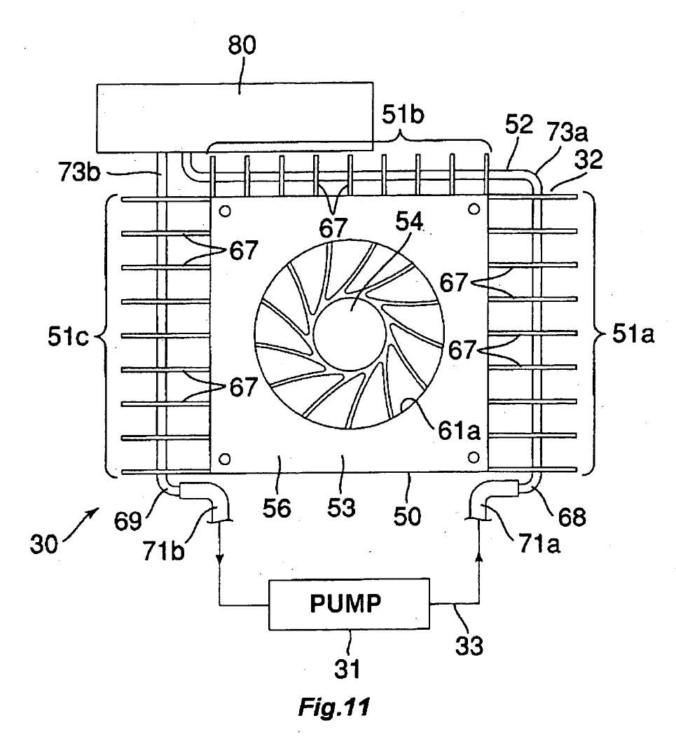

As shown in FIG. 6 and FIG. 8, the first housing 4 accommodates other components, such as a printed circuit board 10 and a hard disk driving device. A CPU 11, which is a heat-generating component, is mounted on the upper surface of the printed circuit board 10. The CPU 11 comprises, for example, a BGA semiconductor package, and is positioned at the rear portion of the first housing 4. The CPU 11 includes a base substrate 12 (FIG. 11), and an IC chip 13 mounted on the base substrate 12 at the center. A heat value of the IC chip 13 during operation is quite high due to its acceleration in processing speed and expansion in functionality, and the IC chip 13 needs to be cooled for maintaining stable operation.

The display unit 3 is a single independent component separated from the body 2. The display unit 3 is provided with a liquid crystal display panel 14 used as a display apparatus, and a second housing 15 that accommodates the liquid crystal display panel 14. The liquid crystal display panel 14 includes a screen 14a on which an image is displayed. The second housing 15 is of a flat box-shape, and a square opening portion 16 is made in the front. The screen 14a of the liquid crystal display panel 14 is exposed to the outside of the second housing 15 through the opening portion 16.

The second housing 15 includes a back plate 17 positioned behind the liquid crystal display panel 14. A pair of convex hollow portions 17a and 17b as shown in FIG. 8 are formed in the back plate 17. The convex hollow portions 17a and 17b are positioned higher than the intermediate portion of the second housing 15 in the height direction. The convex hollow portions 17a and 17b are spaced apart from each other in the width direction of the second housing 15 and each protrudes towards the backside of the second housing 15.

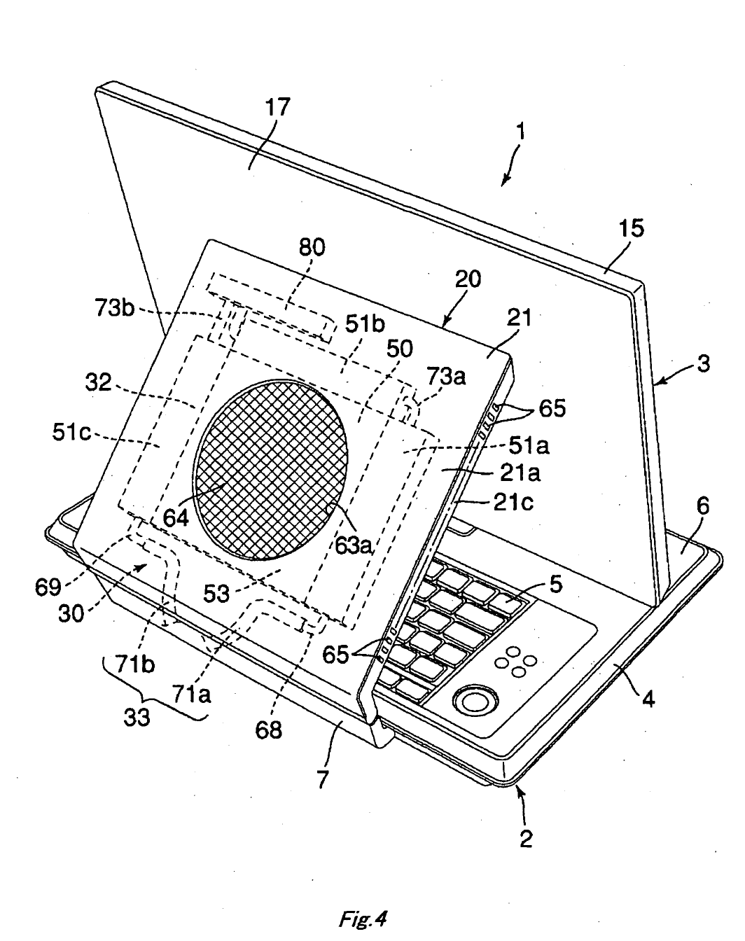

As shown in FIG. 4 through FIG. 8, the display unit 3 is supported by the mounting portion 7 of the body 2 through a supporting member 20. The supporting member 20 includes a third housing 21. The third housing 21 comprises a flat, hollow box including a top plate 21a, a bottom plate 21b, side plates 21c and 21d on the left and right, and a pair of end plates 21e and 21f. The top plate 21a and the bottom plate 21b oppose each other in the thickness direction of the third housing 21. The side plates 21c and 21d and the endplates 21e and 21f lie astride the edge of the top plate 21a and the edge of the bottom plate 21b. The third housing 21 is smaller than the first and second housings 4 and 15 in width.

First through third concave portions 22a, 22b, and 22c are formed in the third housing 21 at one end portion. The first and second concave portions 22a and 22b are spaced apart from each other in the width direction of the third housing 21 so as to correspond to the first and second convex hollow portions 8a and 8b of the mounting portion 7, respectively. The first and second convex hollow portions 8a and 8b fit inside the first and second concave portions 22a and 22b, respectively. The third concave portion 22c is positioned between the first and second concave portions 22a and 22b so as to correspond to the third convex hollow portion 8c of the mounting portion 7. The third convex hollow portion 8c fits inside the third concave portion 22c.

The third housing 21 is coupled to the mounting portion 7 of the first housing 4 at one end portion through a pair of hinges 23a and 23b. One hinge 23a lies astride the first convex hollow portion 8a of the mounting portion 7 and the third housing 21. The other hinge 23b lies astride the second convex hollow portion 8b of the mounting portion 7 and the third housing 21. Each of the hinges 23a and 23b has a horizontal, rotational axis line X1 (FIG. 8) extending in the width direction of the first housing 4. The rotational axis lines X1 of the hinges 23a and 23b are coaxial. The one end portion of the third housing 21 is therefore coupled to the mounting portion 7 of the first housing 4 rotatably about the rotational axis lines X1.

A pair of concave portions 25a and 25b are formed at the other end portion of the third housing 21. The concave portions 25a and 25b are spaced apart from each other in the width direction of the third housing 21 to correspond to the convex hollow portions 17a and 17b of the second housing 15, respectively. The convex hollow portions 17a and 17b fit inside the concave portions 25a and 25b, respectively.

The third housing 21 is coupled to the back plate 17 of the second housing 15 at the other end portion through another pair of hinges 26a and 26b. One hinge 26a lies astride one convex hollow portion 17a of the second housing 15 and the third housing 21. The other hinge 26b lies astride the other convex hollow portion 17b of the second housing 15 and the third housing 21. Each of the hinges 26a and 26b has a horizontal, rotational axis line X2 extending in the width direction of the second housing 15. The rotational axis lines X2 of the hinges 26a and 26b are coaxial. The other end portion of the third housing 21 is therefore coupled to the back plate 17 of the second housing 15 rotatably about the rotational axis lines X2.

In other words, the third housing 21 is allowed to rotate between a position at which the third housing 21 overlaps the back plate 17 of the second housing 15 and a position at which the third housing 21 stays apart from the back plate 17. In addition, the third housing 21 is maintained at the respective positions by braking forces exerted by the hinges 26a and 26b.

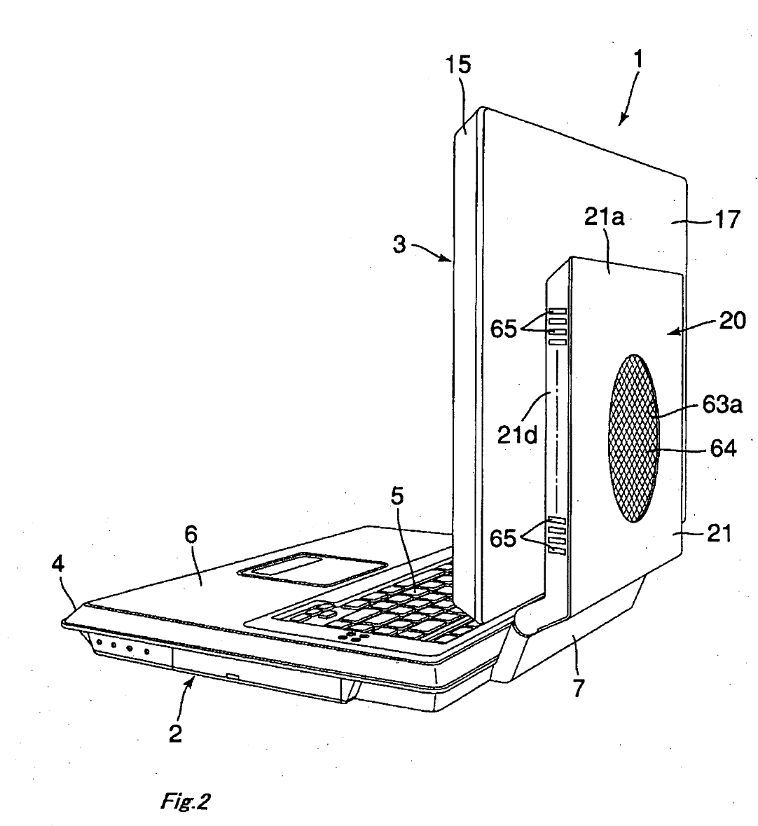

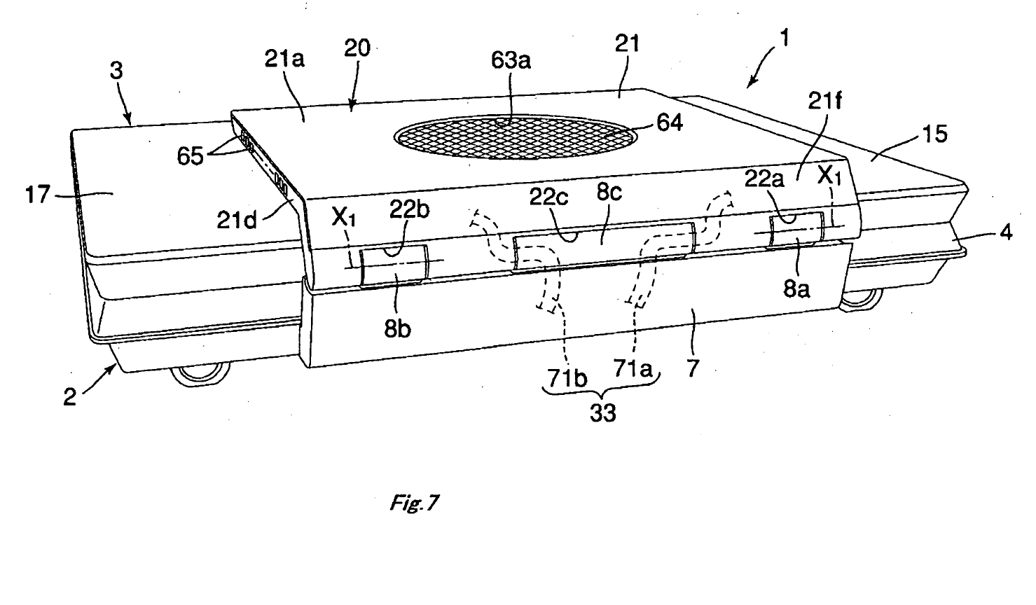

Accordingly, the display unit 3 is coupled rotatably to the body 2 through the supporting member 20, while being allowed to rotate by itself independently from the supporting member 20. To be more specific, the display unit 3, overlapping the supporting member 20, is allowed to rotate between a first position and a second position. FIG. 7 is a view showing a state where the display unit 3 is rotated to the first position, and FIG. 1 and FIG. 2 are views showing a state where the display unit 3 is rotated to the second position. At the first position, the display unit 3 overlies the body 2 to cover the keyboard 5 and the palm rest 6 from above. At the second position, the display unit 3 stands on the rear end portion of the body 2 so that the keyboard 5, the palm rest 6, and the screen 14a are exposed.

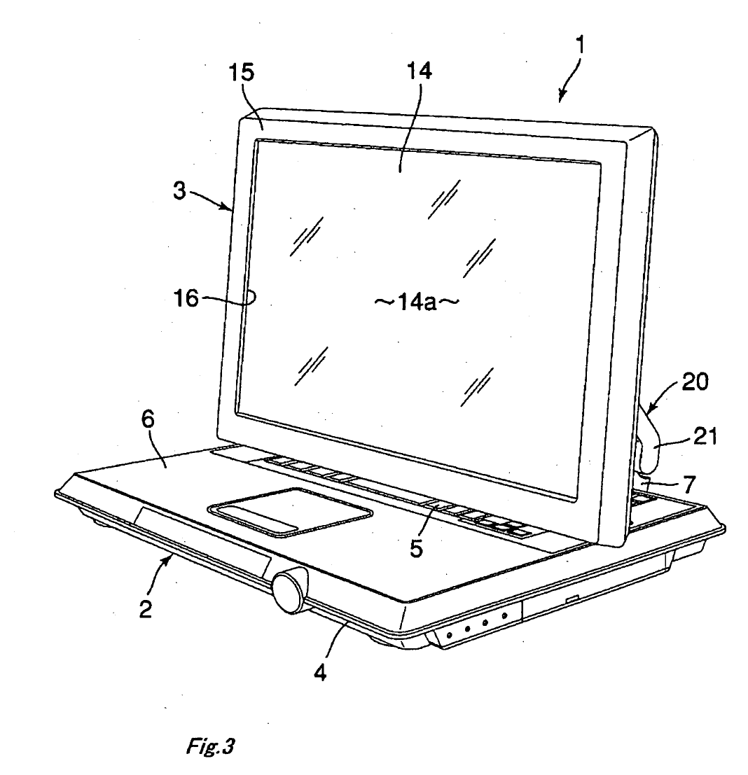

By rotating the display unit 3 upward while the display unit 3 is rotated to and maintained at the intermediate point between the first position and the second position, the back plate 17 of the second housing 15 moves away from the supporting member 20. This in turn, as shown in FIG. 3 through FIG. 6, allows the display unit 3 to move to a third position. At the third position, the display unit 3 stands at a position shifted forward from the second position with respect to the body 2. For this reason, by varying the standing angle of the supporting member 20, it is possible to move the position of the display unit 3 with respect to the body 2 along the depth direction of the body 2. The supporting member 20 is thus kept standing behind the display unit 3 while the display unit 3 is positioned at the second position or the third position. In particular, when the display unit 3 is moved to and maintained at the third position, the third housing 21 of the supporting member 20 is inclined from below upward from the rear end portion of the first housing 4 to the front.

As shown in FIG. 4 and FIG. 8, the portable computer 1 is mounted with a liquid-cooling apparatus 30 that cools the CPU 11. The cooling apparatus 30 is provided with a pump 31, a heat-radiating portion 32, and a circulating path 33.

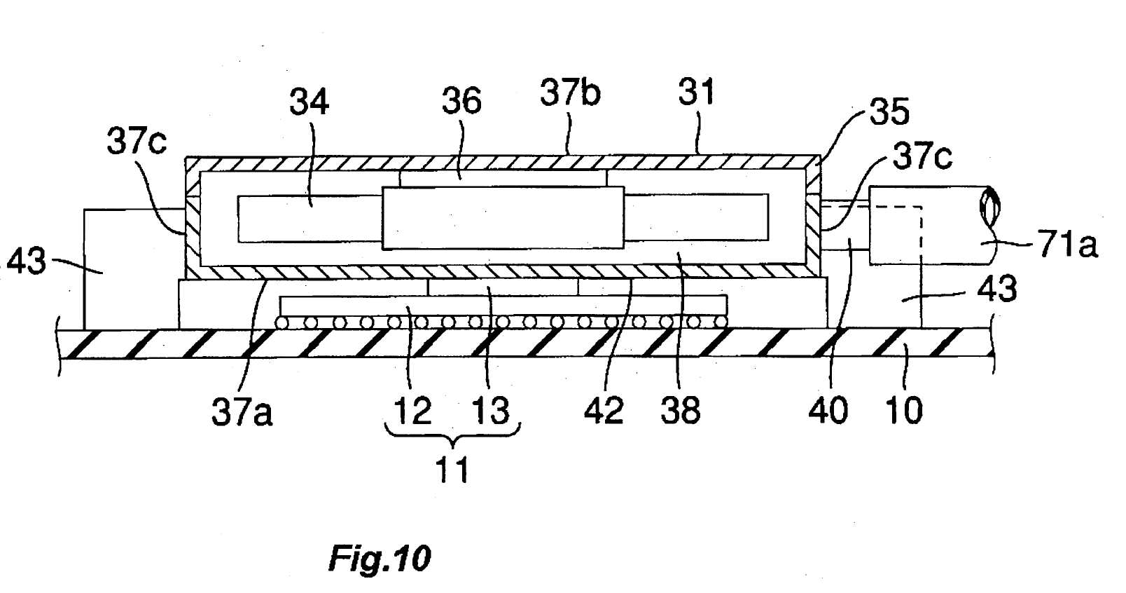

The pump 31 also serves as a heat-receiving portion that receives heat generated in the CPU 11. The pump 31 is accommodated in the first housing 4, and is installed on the upper surface of the printed circuit board 10. As shown in FIG. 10, the pump 31 is provided with an impeller 34 and a pump housing 35 that accommodates the impeller 34. The impeller 34 is driven by means of a flat motor 36, for example, when the power is supplied to the portable computer 1 or the temperature of the CPU 11 reaches a predetermined value.

The pump housing 35 is of a flat box-shape larger than the CPU 11, and is made of a material having excellent heat conductance, for example, aluminum alloy. The pump housing 35 includes a bottom wall 37a, a top wall 37b, and four sidewalls 37c. The walls 37a, 37b, and 37c together define a pump chamber 38 inside the pump housing 35. The impeller 34 is accommodated in the pump chamber 38.

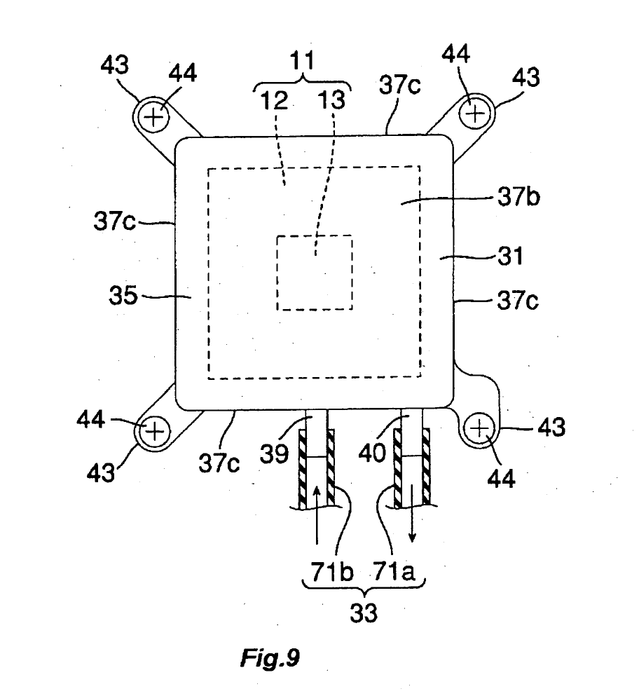

Further, the pump housing 35 includes an intake port 39 (FIG. 9) and a discharge port 40. The intake port 39 and the discharge port 40 open to the pump chamber 38 while protruding from one of the sidewalls 37c of the pump housing 35 toward the backside of the first housing 4.

The lower surface of the bottom wall 37a of the pump housing 35 defines a flat heat-receiving surface 42. The heat-receiving surface 42 is of a size large enough to cover the CPU 11 from above. The pump housing 35 includes four foot portions 43. The foot portions 43 are positioned at the four corners of the pump housing 35, respectively, and each protrudes below the heat-receiving surface 42. Each foot portion 43 is fixed to the upper surface of the printed circuit board 10 through a screw 44. This fixation allows the pump housing 35 to overlap the CPU 11 and the IC chip 13 of the CPU 11 to be thermally connected to the center of the heat-receiving surface 42.

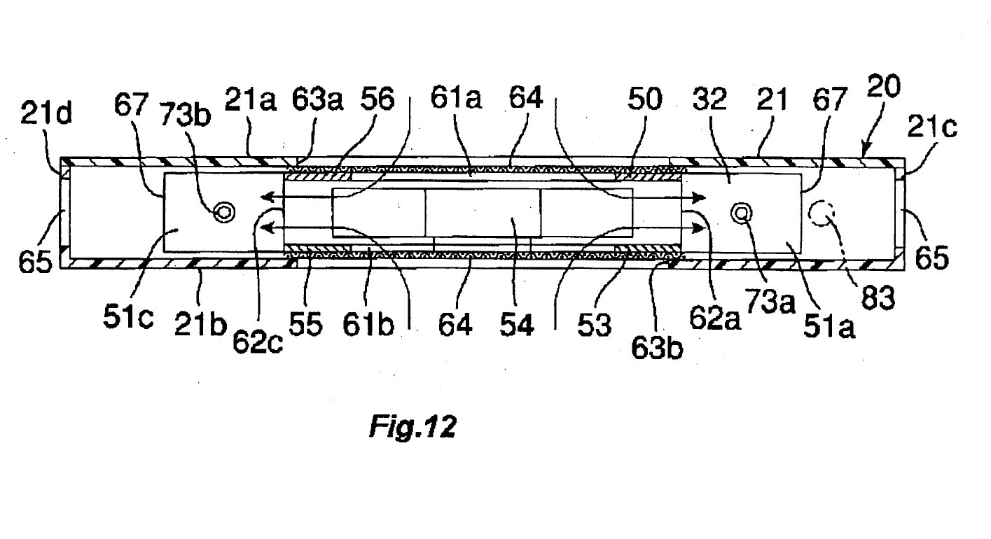

The heat-radiating portion 32 of the cooling apparatus 30 is accommodated in the third housing 21 of the supporting member 20. As shown in FIG. 8, FIG. 11, and FIG. 12, the heat-radiating portion 32 is provided with a fan 50, first through third heat-radiating blocks 51a, 51b, and 51c, and a pipe 52.

The fan 50 includes a fan case 53, and a centrifugal impeller 54 accommodated in the fan case 53. The fan case 53 is made of a material having excellent heat conductance, for example, aluminum alloy. The fan case 53 comprises a square case body 55 and a cover 56. The case body 55 includes a sidewall 58 that stands on the edge on one side, and a pair of boss portions 59a and 59b positioned at the edge on the side opposite to the sidewall 58. The cover 56 is fixed to lie astride the tip end of the sidewall 58 and the tip ends of the boss portions 59a and 59b.

The impeller 54 is supported by the case body 55, and is disposed between the case body 55 and the cover 56. The impeller 54 is driven by an unillustrated flat motor, for example, when the power is supplied to the portable computer 1 or the temperature of the CPU 11 reaches a predetermined value.

The fan case 53 includes a pair of intake ports 61a and 61b, and first through third discharge ports 62a, 62b, and 62c. The intake ports 61a and 61b are made in the cover 56 and the case body 55, respectively, and thereby oppose each other with the impeller 54 in between.

As shown in FIG. 8, the first discharge port 62a is positioned between one end of the sidewall 58 and one boss portion 59a of the case body 55. The second discharge port 62b is positioned between the boss portions 59a and 59b. The third discharge port 62c is positioned between the other end of the sidewall 58 and the other boss portion 59b of the case body 55. The first discharge port 62a and the third discharge port 62c thereby oppose each other with the impeller 54 in between, and the second discharge port 62b thereby opposes the sidewall 58 with the impeller 54 in between.

Consequently, the first through third discharge ports 62a, 62b, and 62c are placed to maintain a positional relation so that they surround the outer periphery of the impeller 54 in three directions. In other words, the first through third discharge ports 62a, 62b, and 62c of the fan case 53 open in three directions with respect to the rotational center O1 of the impeller 54. Thus, compared with the conventional arrangement in which the discharge port opens only in one direction, a wider range of opening with respect to the rotational center O1 of the impeller 54 is secured by the first through third discharge ports 62a, 62b, and 62c.

In the fan 50 arranged as above, when the impeller 54 starts to rotate, as indicated by arrows of FIG. 12, air outside the fan case 53 is taken into the rotational center O1 of the impeller 54 through the intake ports 61a and 61b. The intake air is released inside the fan case 53 from the outer periphery of the impeller 54, and is also discharged to the outside of the fan case 53 through the first through third discharge ports 62a, 62b, and 62c. Hence, according to the fan 50 of this embodiment, cooling air is discharged in three directions of the fan case 53.

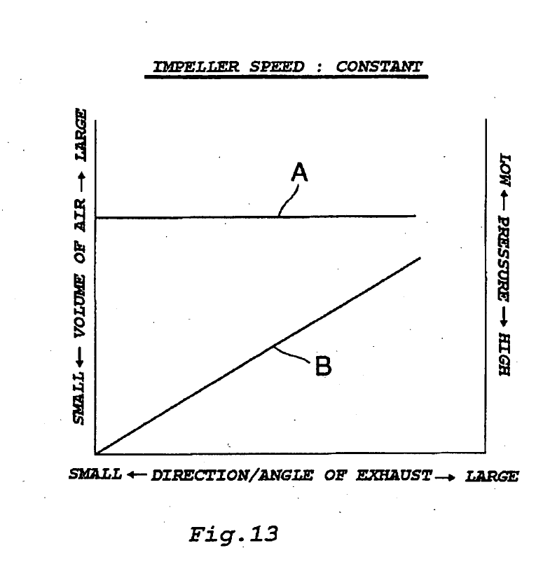

FIG. 13 is a characteristic view showing a relation between a volume and a pressure of cooling air discharged through the discharge ports when the range of opening of the discharge ports with respect to the rotational center of the impeller is varied. Referring to FIG. 13, a line A indicates a pressure of the cooling air discharged through the discharge ports and a line B indicates a volume of cooling air also discharged through the discharge ports. The pressure of the cooling air discharged through the discharge ports is maintained at a constant level regardless of the range of opening of the discharge ports. On the contrary, a volume of cooling air discharged through the discharge ports increases as the range of opening of the discharge ports expands.

Hence, in the case of the fan 50 of this embodiment, by forming the first through third discharge ports 62a, 62b, and 62c that open to the fan case 53 in three directions, it is also possible to increase a volume of cooling air while maintaining a pressure of the cooling air discharged through the discharge ports 62a, 62b, and 62c thus formed. The inventor of the invention conducted an experiment, and it was confirmed that both a volume and a pressure of cooling air discharged through the discharge ports 62a, 62b, and 62c were satisfactory by giving 190? or greater to the range of opening of the first through third discharge ports 62a, 62b, and 62c with respect to the rotational center O1 of the impeller 54.

The fan case 53 of the fan 50 is fixed to the inner surface of the bottom plate 21b of the third housing 21 through screws. The top plate 21a and the bottom plate 21b of the third housing 21 include intake ports 63a and 63b, respectively. The intake ports 63a and 63b are of an opening shape larger than the intake ports 61a and 61b of the fan case 53, and oppose the intake ports 61a and 61b, respectively. The intake ports 63a and 63b are covered with a mesh guard 64 to prevent entrance of a foreign substance, such as a clip.

As shown in FIG. 8, the first discharge port 62a and the third discharge port 62c of the fan case 53 oppose the side plates 21c and 21d on the left and right of the third housing 21, respectively, and the second discharge port 62b opposes the end plate 21e of the third housing 21. The side plates 21c and 21d of the third housing 21 include a plurality of exhaust ports 65. The exhaust ports 65 are aligned in a row at regular intervals, and positioned behind the display unit 3.

The first through third heat-radiating blocks 51a, 51b, and 51c are provided to the first through third discharge ports 62a, 62b, and 62c of the fan case 53, respectively. Each of the first through third heat-radiating blocks 51a, 51b, and 51c includes a plurality of plate-shaped heat-radiating fins 67. The heat-radiating fins 67 are made of a metal material having excellent heat conductance, for example, aluminum alloy. The heat-radiating fins 67 are provided in parallel at regular intervals, and are fixed to the opening edges of the first through third discharge ports 62a, 62b, and 62c of the fan case 53.

The first through third heat-radiating blocks 51a, 51b, and 51c are thereby positioned to surround the impeller 54 of the fan 50 in three directions. Cooling air discharged through the first through third discharge ports 62a, 62b, and 62c of the fan 50 then passes through the heat-radiating fins 67 of the first through third heat-radiating blocks 51a, 51b, and 51c.

The pipe 52 of the heat-radiating portion 32 is made of a metal material having excellent heat conductance, for example, aluminum alloy. As shown in FIG. 8 and FIG. 11, the pipe 52 penetrates through the center of the heat-radiating fins 67 of the first through third heat-radiating blocks 51a, 51b, and 51c, while being thermally connected to the heat-radiating fins 67. Further, the pipe 52 includes a coolant inlet 68 and a coolant outlet 69. The coolant inlet 68 and the coolant outlet 69 are positioned in the vicinity of the coupling portion of the third housing 21 and the first housing 4.

As shown in FIG. 8 and FIG. 11, the circulating path 33 of the cooling apparatus 30 includes a first connecting path 71a and a second connecting path 71b. The first connecting path 71a connects the discharge port 40 of the pump 31 and the coolant inlet 68 of the heat-radiating portion 32. The first connecting path 71a is led to the third convex hollow portion 8c of the first housing 4 (see FIG. 1) from the pump 31 and further to the coolant inlet 68 of the heat-radiating portion 32 through the coupling portion of the convex hollow portion 8c at one end and the third housing 21.

The second connecting path 71b connects the intake ports 39 of the pump 31 and the coolant outlet 69 of the heat-radiating portion 32. The second connecting path 71b is led to the third convex hollow portion 8c of the first housing 4 from the pump 31 and further to the coolant outlet 69 of the heat-radiating portion 32 through the coupling portion of the convex hollow portion 8c at the other end and the third housing 21.

Both the first and second connecting paths 71a and 71b are flexible paths made of rubber or synthetic resin. Hence, even when there is a change in the positional relation between the pump 31 and the heat-radiating portion 32 in association with rotations of the third housing 21, the first and second connecting paths 71a and 71b undergo deformation, thereby absorbing warping of the circulating path 33.

The pump chamber 38 of the pump 31, the pipe 52 of the heat-radiating portion 32, and the circulating path 33 are filled with cooling liquid used as liquid coolant. Used as the cooling liquid is antifreeze liquid made of, for example, water added with an ethylene glycol solution, and a corrosion inhibitor when necessary. The cooling liquid absorbs heat generated in the IC chip 13 while it circulates in the pump chamber 38 of the pump 31.

As shown in FIG. 8 and FIG. 11, the pipe 52 of the heat-radiating portion 32 includes a first path 73a and a second path 73b. The first path 73a includes the coolant inlet 68 and is bent in the shape of a letter L to penetrate through the heat-radiating fins 67 of the first heat-radiating block 51a and the heat-radiating fins 67 of the second heat-radiating block 51b. The first path 73a includes, at the end portion on the side opposite to the coolant inlet 68, an outflow portion 74 through which the cooling liquid is discharged. The second path 73b includes the coolant outlet 69, and extends linearly to penetrate through the heat-radiating fins 67 of the third heat-radiating block 51c. The second path 73b includes, at the end portion on the side opposite to the cooling outlet 69, an inflow portion 75 through which the cooling liquid flows in.

The third housing 21 accommodates a reserve-tank 80. The reserve-tank 80 replenishes the cooling liquid for a loss by evaporation, and reserves a predetermined quantity of the cooling liquid. The liquid level L of the cooling liquid inside the reserve-tank 80 is positioned higher than the center of the reserve-tank 80, and there is an air layer 81 in contact with the liquid level L of the cooling liquid, in the upper portion inside the reserve-tank 80. The air layer serves to compensate for environmental changes as for example temperature and pressure changes that the apparatus may be subjected to experiencing.

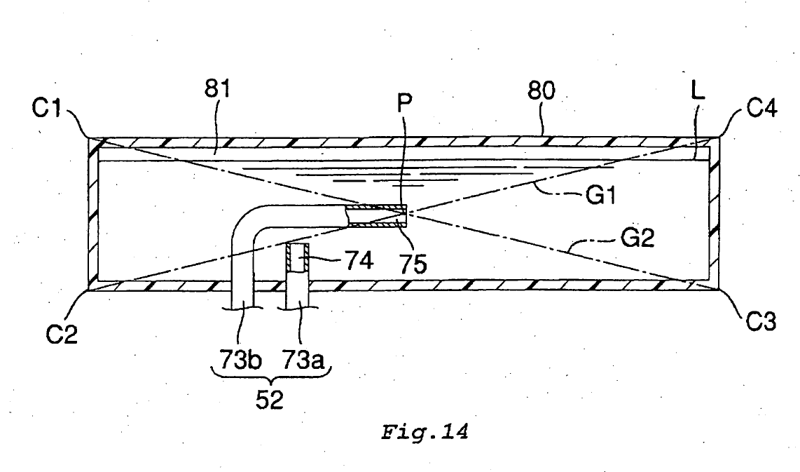

As shown in FIG. 14, the reserve-tank 80 is disposed between the first path 73a and the second path 73b, and is fixed to the bottom plate 21b of the third housing 21 or the heat-radiating portion 32. The reserve-tank 80 is of a flat, square box-shape extending in the width direction of the third housing 21, and includes square four corners C1, C2, C3, and C4. The end portion of the first path 73a on the outflow side and the end portion of the second path 73b on the inflow side are introduced inside the reserve-tank 80 by penetrating through the bottom of the reserve-tank 80.

Both the outflow portion 74 of the first path 73a and the inflow portion 75 of the second path 73b open inside the reserve-tank 80. The outflow portion 74 of the first path 73a is positioned in the vicinity of the bottom of the reserve-tank 80 below the liquid level L of the cooling liquid.

The end portion of the second path 73b on the inflow side is bent at right angles inside the reserve-tank 80, and runs across above the outflow portion 74 of the first path 73a. The outflow portion 74 of the first path 73a and the inflow portion 75 of the second path 73b are thereby oriented to different directions inside the reserve-tank 80.

The inflow portion 75 of the second path 73b is positioned preferably at, optionally near, the center of the reserve-tank 80. In the case of this embodiment, because the reserve-tank 80 is of a square box-shape, as shown in FIG. 14, the inflow portion 75 of the second path 73b is positioned at or nearly at the intersecting point P of two diagonal lines G1 and G2 linking the four corners C1, C2, C3, and C4 of the reserve-tank 80. The inflow portion 75 is thus positioned below the liquid level L of the cooling liquid reserved in the reserve-tank 80, and remains immersed in the cooling liquid constantly, that is regardless of the orientation or attitude of the reserve tank. Thus, even though it is important to maintain an air layer 81 within the reserve tank, the amount of liquid coolant stored within the reserve tank and the position of the inflow portion 75 are restricted such as to permit the inflow portion 75 to be always submerged for every orientation and attitude of the reserve tank, thus preventing air bubbles from entering the circulating path. Such restraints are preferably satisfied by positioning the inflow portion 75 at or near the center of the reserve tank. However, other positions within the reserve tank are possible as long as the air layer is sufficiently small and the liquid layer is sufficiently large so as to constantly submerge the inflow portion 75. By submerging of the inflow portion it is understood that only the tip of the inflow portion where the liquid coolant enters the second tube 73b needs in fact to be submerged. For simplicity, the term “inflow portion” is intended to mean the tip where the cooling liquid flows into the tube 73b.

As shown in FIG. 8, the liquid crystal display panel 14 accommodated in the second housing 15 is electrically connected to the printed circuit board 10 inside the first housing 4 via a cable 83. The cable 83 is led inside the third housing 21 from the liquid crystal display panel 14 through the coupling portion of the convex hollow portion 17a of the second housing 15 and the concave portion 25a of the third housing 21. Further, the cable 83 passes through the third housing 21 in a space between the first heat-radiating block 51a of the heat-radiating portion 32 and the side plate 21c, and is led inside the first housing 4 through the coupling portion of the first concave portion 22a of the third housing 21 and the first convex hollow portion 8a of the first housing 4.

In the arrangement as descried above, the IC chip 13 of the CPU 11 generates heat while the portable computer 1 is operating. Because the IC chip 13 is thermally connected to the heat-receiving surface 42 of the pump housing 35, heat generated in the IC chip 13 is conducted to the pump housing 35. The pump chamber 38 of the pump housing 35 is filled with the cooling liquid, and the cooling liquid absorbs most of the heat generated in the IC chip 13 and conducted to the pump housing 35.

When the impeller 34 of the pump 31 starts to rotate, the cooling liquid inside the pump chamber 38 is sent to the heat-radiating portion 32 via the first connecting path 71a through the discharge port 40, and the cooling liquid is forced to circulate between the pump chamber 38 and the heat-radiating portion 32.

To be more specific, the cooling liquid heated by heat-exchange in the pump chamber 38 is sent to the first path 73a of the heat-radiating portion 32 via the first connecting path 71a, and thereby flows toward the reserve-tank 80 via the first path 73a. The cooling liquid is then discharged into the reserve-tank 80 through the outflow portion 74 of the first path 73a.

In a case where air bubbles are contained in the cooling liquid flowing in the first path 73a, the air bubbles are released into the cooling liquid reserved in the reserve-tank 80. The air bubbles then rise upward in the cooling liquid inside the reserve-tank 80, and are eventually collected into the air layer 81 in the upper portion of the reserve-tank 80. It is thus possible to separate and remove the air bubbles mixed in the cooling liquid inside the reserve-tank 80.

Because the inflow portion 75 of the second path 73b is immersed in the cooling liquid reserved in the reserve-tank 80, it takes in the cooling liquid inside the reserve-tank 80. The cooling liquid is then led to the pump chamber 38 of the pump 31 from the second path 73b via the second connecting path 71b. The first and second paths 73a and 73b of the heat-radiating portion 32 thus form part of the circulating path 33 used to circulate the cooling liquid between the pump 31 and the heat-radiating portion 32.

The first and second paths 73a and 73b, in which the cooling liquid flows, penetrate through the heat-radiating fins 67 of the first through third heat-radiating blocks 51a, 51b, and 51c, while being thermally connected to the heat-radiating fins 67. Heat generated in the IC chip 13 and absorbed in the cooling liquid is thereby delivered to the heat-radiating fins 67 while the cooling liquid flows through the first and second paths 73a and 73b.

The first through third heat-radiating blocks 51a, 51b, and 51c are provided to the three discharge ports 62a, 62b, and 62c of the fan 50, respectively, and surround the impeller 54 in three directions. Hence, when the impeller 54 starts to rotate, cooling air discharged through the discharge ports 62a, 62b, and 62c passes through the heat-radiating fins 67 and is also blown toward the first and second paths 73a and 73b. The heat generated in the IC chip 13 and conducted to the heat-radiating fins 67 and the first and second paths 73a and 73b is thereby carried away on a flow of air.

The cooling liquid cooled by heat-exchange in the heat-radiating portion 32 returns to the pump chamber 38 of the pump 31 via the second connecting path 71b. The cooling liquid then absorbs heat generated in the IC chip 13 again in the pump chamber 38, after which it is sent to the heat-radiating portion 32. As a result, heat generated in the IC chip 13 is transferred successively to the heat-radiating portion 32 by means of the circulating cooling liquid, and is released to the outside of the portable computer 1 from the heat-radiating portion 32.

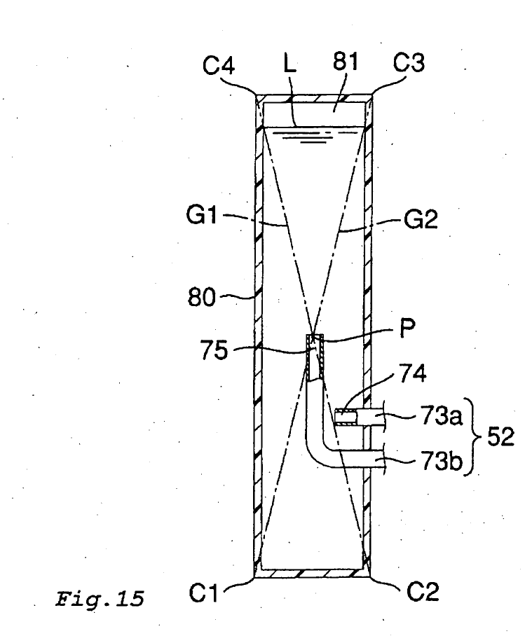

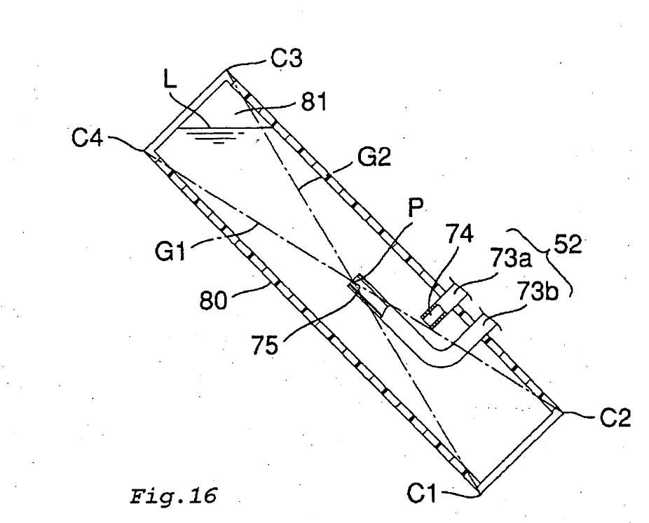

In the portable computer 1 arranged in this manner, for example, when the display unit 3 is rotated from the first position to the second position or the third position, or when the portable computer 1 is carried along or transported, the posture of the third housing 21 accommodating the reserve-tank 80 or the portable computer 1 itself is changed. Accordingly, as shown in FIG. 15 and FIG. 16, the posture of the reserve-tank 80 is changed in many directions, in response to which the position of the liquid level L of the cooling liquid varies.

According to the above arrangement, the in flow portion 75 of the second path 73b that takes in the cooling liquid reserved in the reserve-tank 80 opens in the cooling liquid at the position corresponding to the center of the reserve-tank 80. The inflow portion 75 of the second path 73b thus remains below the liquid level L of the cooling liquid even when the posture of the reserve-tank 80 is changed, and remains immersed in the cooling liquid.

Hence, the inflow portion 75 of the second path 73b will never open to the air layer 81 inside the reserve-tank 80, which makes it possible to prevent air from entering into the inflow portion 75 of the second path 73b. This prevents the cooling liquid from getting mixed with air bubbles while it is circulating back to the pump chamber 38 of the pump 31 from the reserve-tank 80. Heat generated in the CPU 11 can be thus absorbed by the cooling liquid in a satisfactory manner.

Further, according to the above arrangement, mixing of air bubbles into the cooling liquid can be prevented by a simple arrangement, that is, by merely positioning the inflow portion 75 of the second path 73b at the center of the reserve-tank 80. This eliminates the need to additionally provide a complex air-liquid separating mechanism to the reserve-tank 80, and simplifies the structure of the cooling apparatus 30, thereby making it possible to save the cost.

It should be appreciated that the invention is not limited to the embodiment above, and the invention can be modified in various manners without departing from the scope of the invention. For example, the reserve-tank was accommodated in the third housing of the supporting member in the embodiment above; however, the invention is not limited to this arrangement, and the reserve-tank may be accommodated in the first housing of the body unit.

Further, the reserve-tank is not necessarily shaped like a box, and the reserve-tank may be of a cylindrical shape. In this case, it is preferable that the inflow portion of the second path used to take in the cooling liquid is provided at the intermediate portion of the cylinder in the length direction on the axial center of the cylinder.

Also, the pump housing of the pump served also as the heat-receiving portion in the embodiment above; however, the pump and the heat-receiving portion may be separated from each other and provided as independent components.

1. An electronic apparatus, comprising:
a heat-generating component;
a heat-receiving portion thermally connected to the heat-generating component;
a heat radiating portion radiating the heat received by the heat-receiving portion;
a circulating path circulating liquid coolant between the heat-receiving portion and the heat-radiating portion; and
a reserve-tank provided on the circulating path for storing a portion of the liquid coolant;
the circulating path including;
a first path for providing fluid communication of the liquid coolant to the reserve tank; and
a second path for providing fluid communication of the liquid coolant from the reserve tank, said second path having an inflow portion for intake of the liquid coolant from within the reserve-tank, the inflow portion positioned at or near a center portion of the inside of the reserve-tank.

2. An electronic apparatus according to claim 1, wherein the reserve-tank has four corners, and the inflow portion of the second path opens inside the reserve-tank at approximately a position at which two diagonal lines linking the corners intersect.

3. An electronic apparatus according to claim 1, further comprising a pump and wherein the liquid coolant is circulated between the heat-receiving portion and the heat-radiating portion via said pump.

4. An electronic apparatus according to claim 1, wherein the first path includes an outflow portion through which the liquid coolant is discharged into the reserve-tank, and the outflow portion and the inflow portion are opened to different directions inside the reserve-tank.

5. An electronic apparatus according to claim 1, wherein the reserve-tank includes an air layer inside, the air layer positioned above a liquid level of the liquid coolant reserved in the reserve-tank.

6. An electronic apparatus according to claim 1 wherein said liquid level within said reserve tank does not completely filing said reserve tank and leaves an air portion therein, said liquid level within said reserve tank and the position of said inflow portion such that the inflow portion is constantly submerged below a liquid level of the liquid coolant for any attitude of said apparatus.

7. An electronic apparatus, comprising:
a first housing;
a second housing rotatbaly connected to the first housing;
a heat-generating component provided in the first housing;
a heat-receiving portion provided in the first housing, and thermally connected to the heat-generating component;
a heat radiating portion provided in the second housing, and radiating the heat received by the heat-receiving portion;
a circulating path provided between the first housing and the second housing, and circulating a liquid coolant between the heat-receiving portion and the heat-radiating portion; and
a reserve-tank provided in the circulating path and storing a portion of the liquid coolant;
the circulating path including;
a first path for providing fluid communication of the liquid coolant to the reserve tank; and
a second path for providing fluid communication of the liquid coolant from the reserve tank, said second path having an inflow portion for intake of the liquid coolant from within the reserve-tank, the inflow portion positioned at or near a center portion of the inside of the reserve-tank.

8. An electronic apparatus according to claim 7, wherein the reserve-tank has four corners, and the inflow portion of the second path opens inside the reserve-tank at approximately a position at which two diagonal lines linking the corners intersect.

9. An electronic apparatus according to claim 7, further comprising a pump and wherein the liquid coolant is circulated between the heat-receiving portion and the heat-radiating portion via said pump.

10. An electronic apparatus according to claim 7, wherein the first path includes an outflow portion through which the liquid coolant is discharged into the reserve-tank, and the outflow portion and the inflow portion are opened to different directions inside the reserve-tank.

11. An electronic apparatus according to claim 7, wherein the reserve-tank includes an air layer inside, the air layer positioned above a liquid level of the liquid coolant reserved in the reserve-tank.

12. An electronic apparatus according to claim 7, wherein the reserve-tank is provided in the second housing.

13. An electronic apparatus, comprising:
a body;
a support housing rotatably connected to the body;
a display unit rotatably connected to the support member;
a heat-generating component provided in the body;
a heat-receiving portion provided in the body, and thermally connected to the heat-generating component;
a heat radiating portion provided in the support housing, and radiating the heat received by the heat-receiving portion;
a circulating path provided between the body and the support housing, and circulating a liquid coolant between the heat-receiving portion and the heat-radiating portion; and
a reserve-tank provided on the circulating path for storing a portion of the liquid coolant;
the circulating path including;
a first path for providing fluid communication of the liquid coolant to the reserve tank; and
a second path for providing fluid communication of the liquid coolant from the reserve tank, said second path having an inflow portion for intake of the liquid coolant from within the reserve-tank, the inflow portion positioned at or near a center portion of the inside of the reserve-tank.

14. An electronic apparatus according to claim 13, wherein the reserve-tank has four corners, and the inflow portion of the second path opens inside the reserve-tank at approximately a position at which two diagonal lines linking the corners intersect.

15. An electronic apparatus according to claim 13, further comprising a pump and wherein the liquid coolant is circulated between the heat-receiving portion and the heat-radiating portion via said pump.

16. An electronic apparatus according to claim 13, wherein the first path includes an outflow portion through which the liquid coolant is discharged into the reserve-tank, and the outflow portion and the inflow portion are opened to different directions inside the reserve-tank.

17. An electronic apparatus according to claim 13, wherein the reserve-tank includes an air layer inside, the air layer positioned above a liquid level of the liquid coolant reserved in the reserve-tank.

18. An electronic apparatus according to claim 13, wherein the reserve-tank is provided in the support housing.

19. An electronic apparatus, comprising:
a heat-generating component;
a heat-receiving portion thermally connected to the heat-generating component;
a heat radiating portion radiating the heat received by the heat-receiving portion;
a circulating path circulating liquid coolant between the heat-receiving portion and the heat-radiating portion; and
a reserve-tank provided on the circulating path for storing a portion of the liquid coolant;
the circulating path including;
a first path for providing fluid communication of the liquid coolant to the reserve tank; and
a second path for providing fluid communication of the liquid coolant from the reserve tank, said second path having an inflow portion for intake of the liquid coolant from within the reserve-tank, said liquid level within said reserve tank not completely filing said reserve tank and leaving an air portion therein, said liquid level within said tank and the position of said inflow portion such that the inflow portion is constantly submerged below a liquid level of the liquid coolant for any attitude of said apparatus.

20. An electronic apparatus, comprising:
a heat-generating component;
a heat-receiving portion thermally connected to the heat-generating component;
a heat radiating portion radiating the heat received by the heat-receiving portion;
a circulating path circulating liquid coolant between the heat-receiving portion and the heat-radiating portion; and
a reserve-tank provided on the circulating path for storing a portion of the liquid coolant;
wherein the circulating path includes an intake having an inflow portion for intake of the liquid coolant from within the reserve-tank, the inflow portion positioned at or near a center portion of the inside of the reserve-tank.

21. An electronic apparatus as recited in claim 20 wherein the circulating path includes a fist path in fluid communication of the liquid coolant into the reserve tank and a second path for fluid communication of the liquid coolant out of the reserve tank, said inflow portion forming part of said second path.

22. An electronic apparatus according to claim 20, further comprising a pump and wherein the liquid coolant is circulated between the heat-receiving portion and the heat-radiating portion via said pump

23. An method for keeping air out of a reserve tank of an electronic apparatus, which has a heat-generating component; a heat-receiving portion thermally connected to the heat-generating component; a heat radiating portion radiating the heat received by the heat-receiving portion; a circulating path circulating liquid coolant between the heat-receiving portion and the heat-radiating portion; and a reserve-tank provided on the circulating path for storing a portion of the liquid coolant;, the method comprising the steps of:
providing within the circulating path a first path for providing fluid communication of the liquid coolant to the reserve tank;
providing a second path for providing fluid communication of the liquid coolant from the reserve tank, said second path having an inflow portion for intake of the liquid coolant from within the reserve-tank, and
positioning the inflow portion and providing sufficient liquid coolant within said reserve tank such that said inflow portion is constantly submerged below a liquid level of the liquid coolant for any attitude of said apparatus while always maintaining an air portion within said reserve tank.

24. An method for keeping air out of a reserve tank of an electronic apparatus, which has a heat-generating component; a heat-receiving portion thermally connected to the heat-generating component; a heat radiating portion radiating the heat received by the heat-receiving portion; a circulating path circulating liquid coolant between the heat-receiving portion and the heat-radiating portion; and a reserve-tank provided on the circulating path for storing a portion of the liquid coolant;, the method comprising the steps of:
providing within the circulating path a first path for providing fluid communication of the liquid coolant to the reserve tank;
providing a second path for providing fluid communication of the liquid coolant from the reserve tank, said second path having an inflow portion for intake of the liquid coolant from within the reserve-tank, and
positioning the inflow portion at or near a center portion of the inside of the reserve-tank.
